(19) United States
(12) Patent Application Publication
(10) Pub. No.: US 2006/0225651 A1
(43) Pub. Date: Oct. 12, 2006

(54) Method for manufacturing a semiconductor device and apparatus for manufacturing the same

(76) Inventors: Koji Ueno, Kanagawa (JP); Kazutaka Akiyama, Chiba (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/354,024

(22) Filed: Feb. 15, 2006

(30) Foreign Application Priority Data
Feb. 17, 2005 (JP) P2005-041301

(51) Int. Cl. H01L 21/20; C23C 16/00

(52) U.S. Cl. 118/719; 438/584

(57) ABSTRACT

An apparatus for manufacturing a semiconductor device includes: a process chamber configured to contain a substrate having an insulation film; a heating unit configured to degas the substrate; a gas monitor configured to monitor an amount of gas released from the insulation film; a controller configured to control the heating unit to stop the degassing, by determining an endpoint of the degassing using the monitored amount of the released gas; and a film deposition unit configured to deposit a metal film on the insulation film.

### CROSS REFERENCE TO RELATED APPLICATIONS AND INCORPORATED BY REFERENCE

The application is based upon and claims the benefit of priority from the prior Japanese Patent Applications No. P2005-041301, filed on Feb. 17, 2005; the entire contents of which are incorporated herein by reference.

### BACKGROUND OF THE INVENTION

1. Field of the Invention

The present invention relates to a method for manufacturing a semiconductor device and to an apparatus for manufacturing a semiconductor device.

2. Description of the Related Art

Recently, semiconductor devices have become highly integrated by using multi-level interconnect structures. In order to provide the integration, advanced technology is required for each element of the semiconductor device.

In a semiconductor device employing a damascene interconnect structure, for example, an electrical connection between layers is provided by forming a through-hole in an insulation layer and then burying a wiring material in the through-hole. However, a silicon dioxide insulation film or the like with silicon as the main component has intrinsically high hygroscopicity. When a wiring material is deposited on the surface of an insulation film, which has captured gases with water molecules, various problems will occur such as oxidation of the wiring, and degradation of adhesion between laminated materials caused by the oxidation. Therefore manufacturing yield of the semiconductor device will be decreased, and reliability of the semiconductor device will be decreased.

There is a known method in which a connection hole is formed in an interlayer dielectric, and then a degassing treatment is performed to dehydrate from the interlayer dielectric by heating so as to improve the adhesion between a barrier conductor film embedded into a connection hole and the connection hole.

However, even among semiconductor devices manufactured with the same specification, there is some slight difference in amount of adsorption of gasses such as water vapor to the semiconductor devices. This problem occurs in every production line or every production lot. Therefore, a degassing treatment conducted under the same conditions is insufficient to provide the necessary degassing treatment for every semiconductor device. On the other hand, a more complete degassing treatment that conducts more degassing than necessary will decrease production of the semiconductor devices.

### SUMMARY OF THE INVENTION

An aspect of the present invention inheres in a method for manufacturing a semiconductor device, including: depositing an insulation film on a substrate; starting a degassing the insulation film; monitoring an amount of gas released from the insulation film during the degassing; determining an endpoint of the degassing based on the amount of released gas, and stopping the degassing at the endpoint; and depositing a metal film on the insulation film after the degassing.

Another aspect of the present invention inheres in an apparatus for manufacturing a semiconductor device, including: a process chamber configured to contain a substrate having an insulation film; a heating unit configured to degas the substrate; a gas monitor configured to monitor an amount of gas released from the insulation film; a controller configured to control the heating unit to stop the degassing, by determining an endpoint of the degassing using the monitored amount of the released gas; and a film deposition unit configured to deposit a metal film on the insulation film.

### BRIEF DESCRIPTION OF THE DRAWINGS

FIGS. 1A, 1B, 2A, 2B, 3A, 3B and 4 are sectional process views showing a method for manufacturing a semiconductor device according to an embodiment of the present invention;

FIG. 5 is a flow chart showing the processes from a degassing treatment to a film formation process by sputtering;

FIG. 6 is a graph showing an example for explaining that the degassing is terminated by analyzing a detected amount of released gasses;

FIG. 7 is a graph showing that release of water proceeds as the temperature rises in a thermal desorption spectroscopy (TDS) analysis;

FIG. 8A is a schematic diagram showing an apparatus according to the embodiment of the present invention;

FIG. 8B is a schematic diagram showing an apparatus according to the embodiment of the present invention; and

FIG. 9 is a diagram showing a result of a Stress Migration (SM) test for 500 hours at 200 degrees Celsius.

### DESCRIPTION OF THE INVENTION

An embodiment and various modifications of the present invention will be described with reference to the accompanying drawings. It is to be noted that the same or similar reference numerals are applied to the same or similar parts and elements throughout the drawings, and the description of the same or similar parts and elements will be omitted or simplified.

The method for manufacturing a semiconductor device according to the present invention is advantageously performed in production of the semiconductor devices with a damascene interconnect structure. In the following, referring to the appended drawings, the embodiments of the present invention will be described along the manufacturing steps of a damascene interconnect.

Recently, as circuit patterns of semiconductor devices have been miniaturized, materials with small dielectric constant have been studied a use as an interlayer dielectric in order to provide high speed processing by limiting the dielectric constant to a lower level. Compositions of silicon hydrogen (SiH), silicon carbonate (SiC), silicon carbonate nitride (SiCN), silicon carbonate oxidize (SiCO), silicon carbonate hydride (SiCH) and the like, respectively, are representative of materials with a small dielectric constant. The materials have been studied from the viewpoint of their morphology, for example, by making the materials porous to reduce the respective densities thereof.

On the other hand, there has been a problem that a silicon-rich insulation film including a silicon dioxide film, which is conventionally frequently used, is liable to adsorb gasses such as water vapor from the external atmosphere of the operation site. The insulation film absorbs atmospheric gasses, especially water vapor, during or after forming the film to bring about a physical or chemical adsorption reaction. The surface of the material, after adsorption, is chemically and physically different from that before adsorption. The adsorbed surface has various disadvantageous effects on wiring materials such as copper (Cu), aluminum (Al), tungsten (W) or tin (Sn) to be formed on the adsorbed surface.

For instance, when a barrier metal film is formed in order to perform a copper damascene process, an insulation film that has adsorbed gasses will partially oxidize the surface of the formed barrier metal film to change it into an insulator. The barrier metal film modified due to oxidation provides a completely different grain orientation for the copper wiring deposited on the barrier metal film. As a result, adhesion between the barrier metal film and the copper wiring is significantly degraded.

In semiconductor device manufactured in the manner described above the copper wiring material will cause migration according to the stress distribution existing in the interior of the structure after long-term operation, due to accompanying heat generation. As a result, a stress void will be generated which will increase electrical resistance of a via-hole contact and cause electrical defects.

The problem as described above is generally more serious in the case where an organic insulation material with a small dielectric constant is employed, since the material is more liable to be modified while it is processed. An interlayer dielectric including SiC, for example, is liable to be damaged while it is processed by dry etching, etc. The damaged surface of the SiC film is partially changed into a composition close to silicon dioxide and into a material more liable to collect or capture water than the original SiC film. A material in which the density is limited to a low level, for example, a porous material is remarkably more liable to collect or capture water. Also, generation of the stress voids, electrical resistance of the via-hole contacts, and frequency of occurrence of electrical defects are highly increased.

Both the method for manufacturing semiconductor devices and the apparatus for manufacturing the same according to the embodiment of the present invention solve the problem as described above by a degassing treatment after the adsorption of gasses. However, a necessary and sufficient degassing treatment, even for semiconductor devices manufactured with the same specification, is slightly different from one another in every production line or every production lot, depending upon past process records, etc. Therefore, it is not preferable to perform a degassing treatment, based on the same conditions, for every semiconductor device and to aim for a more complete degassing treatment than necessary, comprehensively considering a production yield and productivity as well as reliability of the final products. A manufacturing method is required in which the semiconductor devices manufactured with the same specification can be mass-produced efficiently and with high reliability.

The method for manufacturing semiconductor devices and the apparatus for manufacturing the same according to the embodiment of the present invention comprehensively solves the problems described above.

Various embodiments can concretely provide the characteristic indicating an endpoint for a degassing treatment and for the way to determine such characteristic.

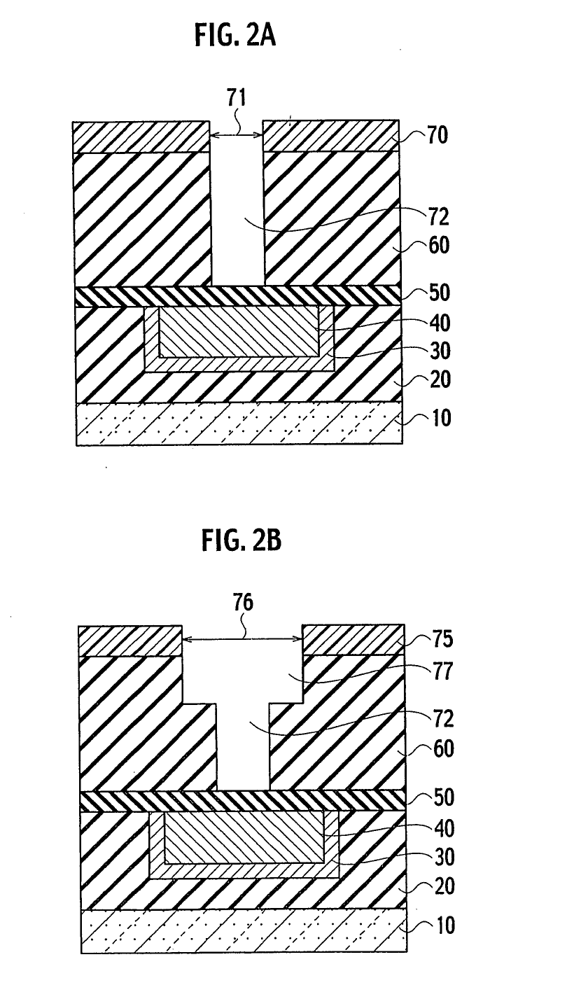

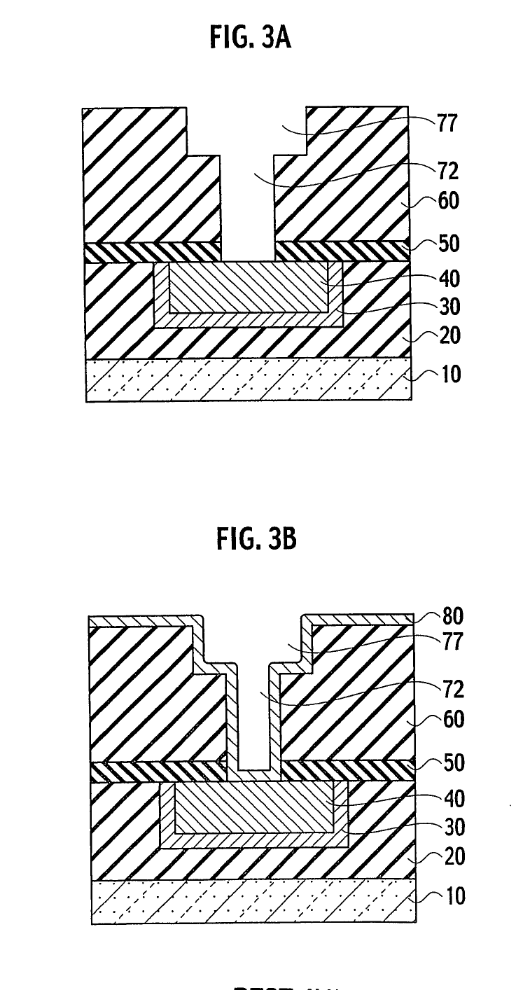

Most simply, as shown in FIGS. 5 and 6, the embodiment takes into account the amount of released gasses by continuous monitoring so as to obtain the total amount of released gasses (an integrated amount of gas) and it is logically determined, for every prescribed period, whether the integrated amount of gas has reached a predetermined amount (a specified amount of gas).

In the embodiment, as shown in FIG. 6, the graph shows the integrated amount of gas that is obtained for every prescribed period on the basis of the detected amount of released gasses. The specified amount of gas is a specific value of the integrated amount of gas and is specified beforehand as a characteristic value indicating an endpoint for the degassing treatment.

Before step S1 shown in FIG. 5, an insulation film is deposited on a substrate. In step S1, a degassing treatment for degassing the insulation film is started by heating the film and substrate. In step S2, an amount of gas released from the insulation film is monitored during the degassing treatment. In step S3, an endpoint of the degassing treatment is determined, based on the amount of released gas, and the degassing treatment is stopped at the endpoint. In step S3, if it is determined that the integrated amount of gas does not correspond to a specified amount of gas, the degassing treatment is continued by continuously heating the insulation film on the substrate. The logic determination is repeated for every prescribed period. When the integrated amount of gas to be released corresponds to the specified amount of gas, the degassing treatment is ended by stopping the heat treatment. In step S4, a metal film is deposited on the insulation film after the degassing treatment.

The manufacturer may specify beforehand an appropriate value as the specified amount of gas, based on a preliminary study of the relation between the integrated amount of gas and the occurrence of defects corresponding to the gas release characteristics that are different for every semiconductor device. Specifying an appropriate value for the specified amount of gas may be performed for each semiconductor device.

It is believed that occurrence of a defect at a via-hole contact is mainly due to the absorption of water by the insulation film. Consequently, when water vapor of more than a predetermined amount is detected as an integrated amount of gas during a degassing treatment, it is possible to prevent defect from occurring even though there are some variations among the integrated gas quantities of the respective semiconductor devices.

When there is a plurality of different gasses, at least one or more of the plurality of s gasses can be chosen. Through detecting an integrated amount of gas of vapor (H₂O), which leads to a via-hole contact defect, which is chosen from a plurality of the gasses, the amount of released gasses can be more sensitively detected using the integrated amount of gas.

Furthermore, the amount of gasses released per unit time may be obtained for every prescribed period, for example, every ten seconds. The degassing treatment will be stopped when the amount of released gas decreases to less than the predetermined amount. In this case, the amount of gasses released per unit time is monitored. When the amount of gasses released per unit time reaches the predetermined amount indicating the end of the degassing treatment, the degassing treatment is stopped and the metal film is formed.

In another embodiment, the amount of gasses released per unit time is obtained for every prescribed period, for example every ten seconds, and the amount of released gas in the processing ten seconds is compared with the amount at the present to obtain a difference there between, and when the difference decrease to less than the given value, the end of degassing is determined so as to start forming a metal film, such as a barrier metal film. In this case, monitored is the difference between the amounts of gasses released per unit time obtained every prescribed period on the basis of sensing the amount of released gasses. When the difference is less than or equal to the predetermined value, it is determined that the degassing treatment should be stopped so as to start forming a metal film.

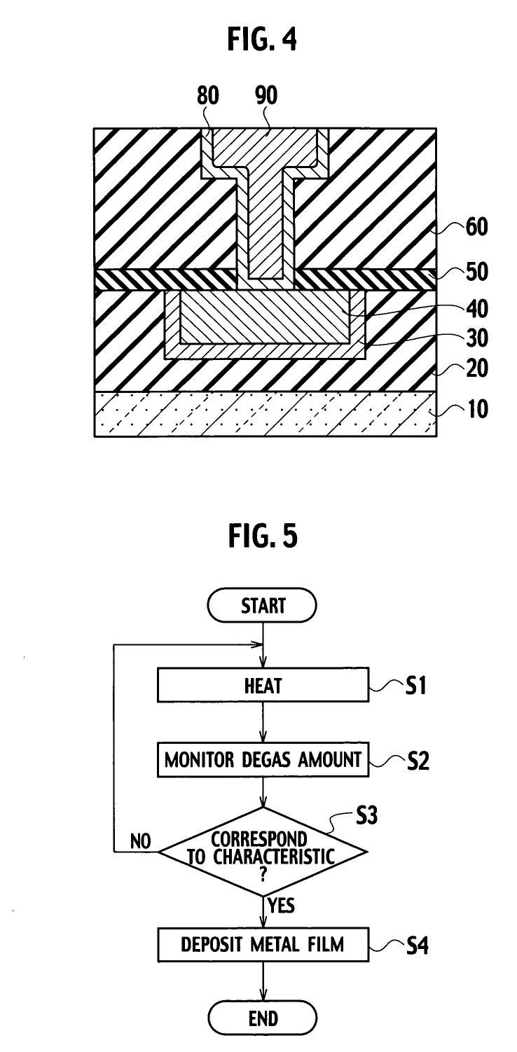

Adsorption of a gas molecule on an insulation film is classified according to the types of adsorption. The classification is two categories, physical adsorption and chemical adsorption (chemisorption) accompanying chemical reaction. FIG. 7 shows a result of a Thermal Desorption Spectroscopy (TDS) analysis of an insulation film, and shows “two peaks” consisting of a desorption peak of the physical adsorption and a desorption peak of the chemical adsorption on the higher temperature side.

Chemical adsorption is usually strong as well as hard to be easily desorbed, and the harder to be desorbed it is, the less adverse influence on the semiconductor devices it has. A physically adsorbed body causes oxidation and that is desirable to be desorbed beforehand. As shown in the result of the TDS analysis, desorption reaction is accelerated by providing heat energy and generally proceeds gradually as time passes. The embodiment, in which the end of degassing is determined on the basis of difference in gas release based on a comparison per unit time, is a desirable embodiment for stopping the degassing treatment at an intermediate stage of desorption and efficiently preventing the occurrence of contact defects.

In the embodiment where the determination to stop degassing is made on the basis of a difference, it is not essential to consider the amount of gasses released per unit time. That is, an instantaneous value of the amount of released gasses, and the integrated amount during the interval of sampling (for example, ten seconds) may be employed.

As an example of applications, of the various, described concrete embodiments, molecules of only a specified gas selected from water vapor or gasses other than water vapor, such as hydrogen molecules, carbon monoxide, carbon dioxide, and oxygen molecules, may be released, from an insulation film up on heating. Such an embodiment, in which only released molecules of a specified gas is effectively utilized according to a result of analyzing the mechanism for the occurrence of defects.

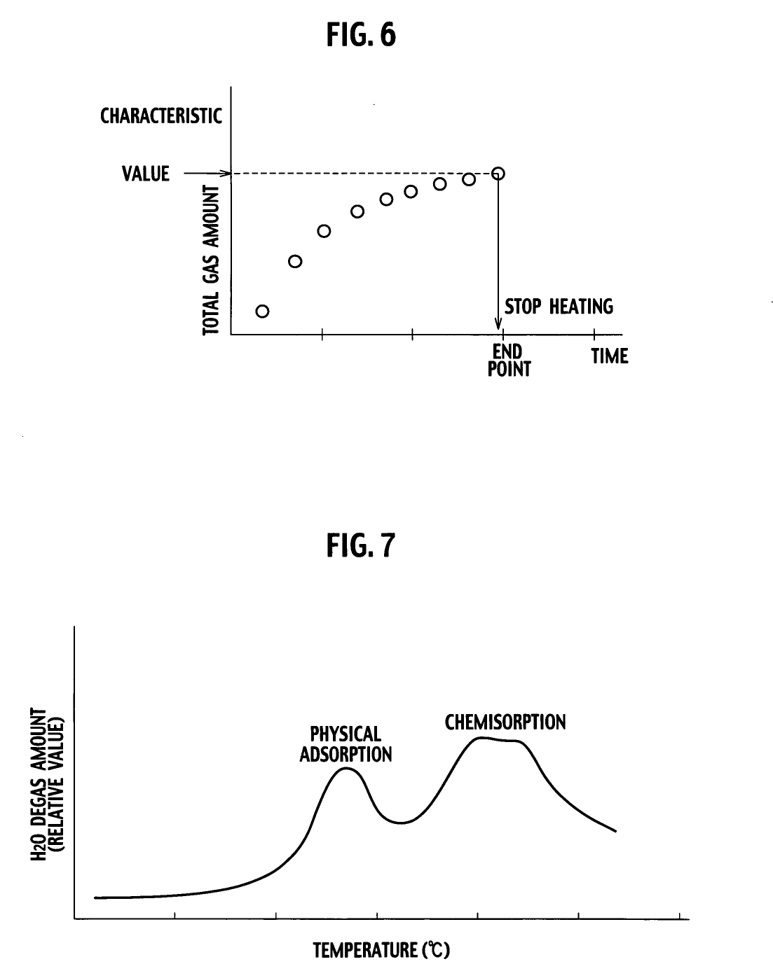

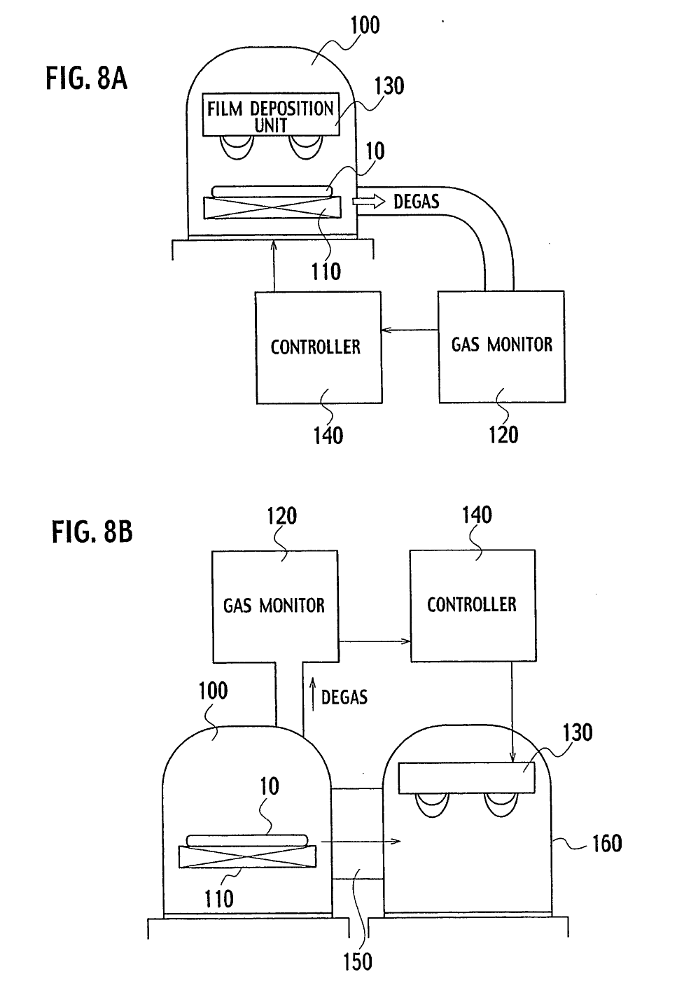

As shown in FIG. 8A, an apparatus for manufacturing semiconductor devices according to the embodiment of the present invention comprises a process chamber 100, a heating unit 110 for heating a substrate 10 mounted in the process chamber 100, a gas monitor 120 for obtaining the amount of gasses released into the process chamber 100, a film deposition unit 130 for forming a metal film 80 on the substrate 10, and a controller 140 for identifying a predetermined characteristic in the released amount of gas obtained by the gas monitor 120 and for starting to operate the film deposition unit 130 at the time of identifying the characteristic.

The substrate 10, on which an insulation film has been deposited, is mounted in the process chamber 100 and is heated by the heating unit 110. The heating unit 110 is, for example, a hot plate and the whole body of the substrate 10 and the individual layers deposited on the substrate 10 can be heated by mounting the substrate 10 on the hot plate. Otherwise, the substrate can be heated by radiation of infrared rays using an infrared rays generator.

The gas monitor 120 obtains the amount of released gasses emitted into the process chamber 100 and the information is provided via the controller 140 for judging on determining the operation of the entire apparatus. For example, the amount of released gasses can be obtained by making a TDS analysis performed using a TDS analyzer in such a way that the sample is maintained at a constant temperature. Otherwise, the gas monitor 120 obtains the released amount of one or more predetermined gasses from the mixed-gas, which is a mixture of a plurality of gasses. The gas monitor 120 may include a unit that can analyze and obtain the amount of released gas for every molecular species of the predetermined gasses.

When the predetermined characteristic indicating the end of degassing is determined via the amounts of released gasses obtained by the gas monitor 120, the controller 140 will stop the operation of the heating unit 110 and start forming a metal film by controlling the film deposition unit 130.

The controller 140 can be provided in a configuration in which it receives information about the amount of released gasses as electrical signals from the gas monitor 120, and analyzes the received information by executing a program in the existing computer system to determine the result of the analysis. The controller 140 also transmits and receives electrical signals to and from the driving systems of the heating unit 110 and the film deposition unit 130.

Various systems can be used as the film deposition unit 130, corresponding to the types of the metal film to be formed. Various systems, such as a sputtering system, a chemical vapor deposition (CVD) system, or an atomic layer deposition (ALD) system, are available.

When the metal film is formed under the prescribed conditions, the operation of film deposition unit 130 will be stopped and the substrate 10, on which the film has been formed, will be transferred out of the process chamber 100. Subsequently, a similar substrate 10, on which a metal film is to be formed, is transferred into the process chamber 100, and each operation of the apparatus will be repeated.

After the degassing treatment is finished, it is preferable for the metal film to be formed without again exposing the insulation film to the atmosphere which includes moisture and other gaseous components. For that purpose, the apparatus shown in FIG. 8A is configured so as to perform a film-forming process immediately after the degassing treatment without changing the atmosphere. For this purpose, the heating unit 110, on which the substrate 10 is mounted, in the lower portion of the process chamber 100 and the film deposition unit 130 is provided in the upper portion of the process chamber 100.

In FIG. 8B, a chamber including a heating unit 110 is separated from a chamber including a film deposition unit 130 and both the chambers are connected together via a transfer tool 150. In this case, the compactness of the configuration of FIG. 8A is lost, but the film formation is achieved in a clean atmosphere, while the remaining released gasses in the process chamber 100 are removed. Therefore, it is easy to prevent reoxidation of a barrier metal film by the released gasses. As long as both the chambers in communication have a common atmosphere, it is possible to easily deposit the barrier metal film.

Using the apparatus for manufacturing semiconductor devices according to the embodiment of the present invention, the method for manufacturing semiconductor devices can be efficiently performed.

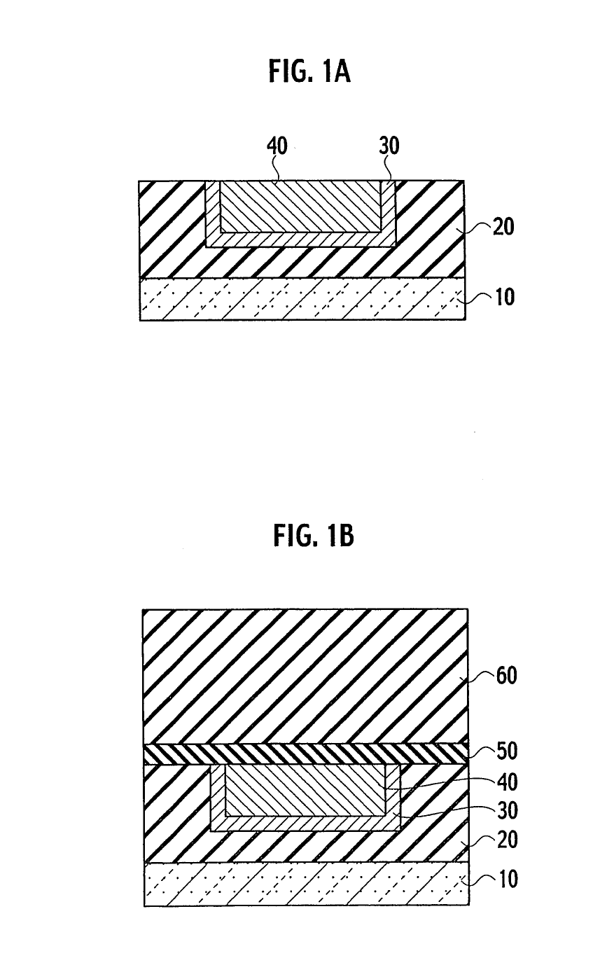

As shown in FIG. 1A, it is assumed that the underlying wiring structure including a barrier metal film 30 and an underlying wiring 40 will be formed with a damascene structure within an insulation layer 20 provided on a substrate 10. The underlying wiring 40 composing the damascene structure is embedded into a damascene trench with thin barrier metal films 30 formed on both the bottom and the sidewall of the trench. The trench is provided within the insulation layer 20.

First, as shown in FIG. 1B, a barrier layer 50 and an interlayer dielectric 60 are deposited sequentially on the surface onto which the insulation layer 20, the barrier metal film 30, and the underlying wiring 40 are exposed.

Here, the barrier layer 50 is deposited, for example, as a silicon nitride (SiN) film a film thickness of about 100 nm. For the interlayer dielectric 60, silicon dioxide (SiO₂) as well as materials of various compositions such as SiH, SiC, SiCN, SiCO and SiCH, which are useful to lower the dielectric constant, can be employed. The organic insulation materials including carbon can contribute to a reduction in the dielectric constant since they can restrain both molecular polarization and density of the material to a low level. These insulating materials are deposited, for example, at a thickness of about 500 nm.

Next, a photoresist film 70, with an opening 71 in the area on which a via-hole is to be formed, is formed on the surface of the interlayer dielectric 60 by a lithography process. The opening 71 is a circular opening, for example, with a diameter of about about 0.2 μm. Using the photoresist film 70 with the opening 71, the interlayer dielectric 60 is selectively etched by reactive ion etching (RIE). The etching reaction stops at the barrier layer 50, and a trench 72 with a depth of about 500 nm, passing through the via-hole forming space, is formed in the interlayer dielectric 60, as shown in FIG. 2A.

Next, a photoresist film 75, with an aperture 76 in the area on which an overlying wiring is to be formed, is formed on the surface of the interlayer dielectric 60 by a lithography process. The aperture 76 is a circular opening, for example, with a diameter of about 0.4 μm. Using the photoresist film 75 with the aperture 76, the interlayer dielectric 60 is again selectively etched by RIE to form a recess 77 with a depth of about 200 nm for the overlying wiring recess, as shown in FIG. 2B.

Next, the barrier layer 50, exposed at the bottom of the trench 72, is etched by RIE to epose the underlying wiring 40. FIG. 3A shows the state where the photoresist film 75 is removed after exposing the underlying wiring 40. Then, while the substrate 10 is kept under a reduced-pressure, the degassing treatment is performed by heating with the heating unit 110. The gasses released into the process chamber 100 are collected, for example, through an inlet communicating with the gas monitor 120, and the amount thereof is measured in real time by the gas monitor 120.

The relation between a residual rate of the adsorbed gasses on the interlaminated insulation layer 60 and a rate of incidence of via-hole contact defects is obtained beforehand. The residual rate of the adsorbed gasses below which the rate of incidence of the defects fall within the acceptable range, and a release characteristic with which the permissible residual rate can be determined are also previously determined.

The release characteristics of a degassing process are, for example, the amount of a specified gas species released per unit time, an integrated amount of the gasses released throughout the degassing treatment, or a difference between the amount of all gasses measured every prescribed period. The acceptable range of the residual rate of the adsorbed gasses can be determined by comparing these predetermined values (characteristics), which have been determined, with the release characteristic. For that purpose, the gas monitor 120 should be continuously operated to obtain the amount of the released gasses in real time, and also the degassing treatment should be continuously performed until the specified characteristic are determined by measurement.

For instance, the SiCH interlayer dielectric 60 with a thickness of about 500 nm is deposited, and the trench 72 and the recess 77 are formed. Then, the degassing treatment of the interlayer dielectric 60 is performed by evacuating the interior of the process chamber 100, in which the barrier metal film 80 is formed, as well as by leaving it at a temperature of 300 degrees Celsius as provided by the heating unit 110 subsequently, tantalum nitride is deposited as a barrier metal film 80 by a sputtering process.

At that time, the released gasses are sent into the gas monitor 120, and the amount of the gasses released per unit time is measured every ten seconds. For example, if the condition that the amount of the released gasses reaches the detection limit, defined by the gas monitor 120, is necessary and sufficient condition, the degassing treatment may be continued until an instant when the gas monitor 120 indicates the detection limit.

When the characteristic, which is the criterion for the end point, appears on the amount of degassing, the degassing is finished. Then, as shown in FIG. 3B, a barrier metal film 80 is formed on the bottom and side wall of the trench 72 in the via-hole forming space and of the recess 77 for the overlying wiring, respectively, formed in the interlayer dielectric 60. For the barrier metal film 80 such materials as tantalum (Ta), tantalum nitride (TaN), titanium (Ti), titanium nitride (TiN) tungsten nitride (WN), niobium (Nb) and niobium nitride (NbN) can be used with a thickness of about 15 nm. Film formation may be typically carried out by sputtering. However, a chemical vapor deposition (CVD) process, an atomic layer deposition (ALD) process, etc. can also be employed, depending on the type of film materials.

Then, as shown in FIG. 4, a wiring material 90 is deposited over the barrier metal film 80, and the overlying wiring structure is completed by applying a planerization process, such as a chemical-mechanical polishing (CMP) process, to the barrier metal film 80 and the wiring material 90. It is desirable to use copper (Cu) as a wiring material 90 because copper can enhance the merits of a dual damascene process. For that purpose, after forming a thin Cu seed film with a thickness of about 100 nm, by a sputtering process, it will be preferable to embed both the trench 72 in the via-hole forming space and the recess 77 for the overlying wiring with an electroplated metallic copper (Cu).

A plurality of semiconductor devices with the same specification can be continuously manufactured by repeating the steps described above.

When the state of the wiring in the semiconductor devices, which have been manufactured by depositing a SiCH film with a thickness of about 500 nm as the interlayer dielectric 60 was inspected, there were no problems in any of a plurality of semiconductor devices manufactured according to the same circuit specification, and the production yield of the via-holes was excellent. Further, a stress migration (SM) test was carried out, and it was confirmed that no via-hole defects were detected, even after maintaining the semiconductor devices at a temperature of 200 degrees Celsius for 1000 hours.

A method for manufacturing was tried in which the semiconductor devices were left as they were in an ambient atmosphere for four different periods (A: 0.5 hours, B: 24 hours, C: 72 hours, D: 168 hours) after forming the interlayer dielectric 60, and after forming the trench 72 and the recess 77, and before the degassing treatment. This method was performed on the assumption that device might be left out in an ambient atmosphere during the real production process.

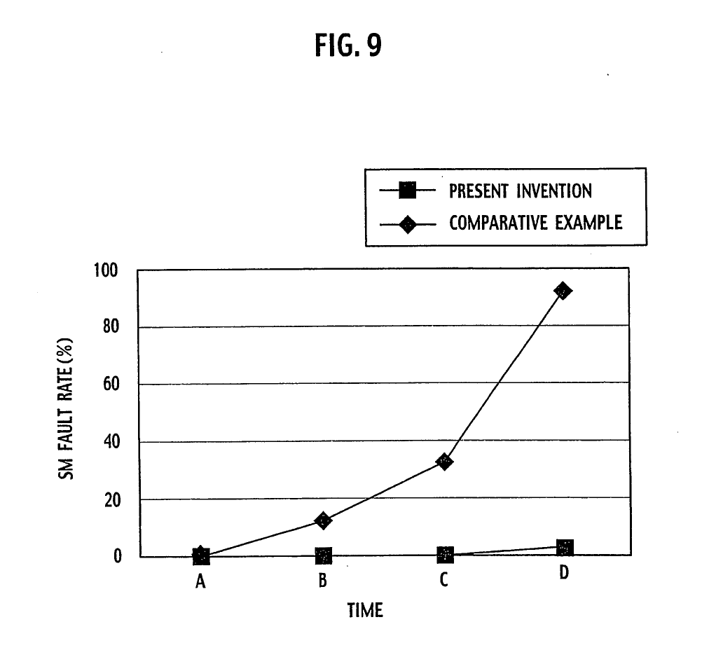

As shown in FIG. 9, the result of a SM test (the semiconductor devices are heated at a temperature of 200 degrees Celsius and left as they are for 500 hours) is acceptable in this case and the fractured defect of the via-holes is substantially zero. Consequently, the production yield is very high. In FIG. 9, the fractured defect is calculated on the basis of the judgment that a via-hole is judged to be a defective if the increment of electrical resistance of a via-hole contact exceeds 10%.

Further for comparison's sake, both an inspection of the state of the wiring just after processing and a SM test, where the semiconductor devices were heated at a temperature of 200 degrees Celsius for a prescribed period, were carried out for a plurality of semiconductor devices with the same circuit specification in which the degassing treatment was evenly performed for 30 seconds. As a result, with regard to the semiconductor devices for which any standstill periods (the devices were left for the periods described above) were not set, the production yield considering the via-holes just after processing was excellent, but the evaluated result of the SM test was negative for all the semiconductor devices.

With regard to the semiconductor devices for which standstill periods different from one another were set, as shown in FIG. 9, the fractured defects after 500 hours while keeping the devices heated at 200 degrees Celsius becomes significantly high as the standstill periods become longer. Even with regard to the semiconductor devices for which standstill periods were not set, defects occurred at via-holes after 500 hours in the SM test, and for a typical instance, copper material in a via-hole migrated up to the upper portion of the via-hole resulting in an open circuit failure at the bottom of the via-hole.

As described above, according to the embodiment of the present invention, when a plurality of semiconductor devices with the same circuit specifications are produced continuously, semiconductor devices, which have an excellent production yield and productivity, as well as reliability, particularly from the viewpoint of SM resistance, can be manufactured.

Various modifications will become possible for those skilled in the art after receiving the teachings of the present disclosure without departing from the scope thereof.

What is claimed is:

1. A method for manufacturing a semiconductor device, comprising:
depositing an insulation film on a substrate;
starting a degassing the insulation film;
monitoring an amount of gas released from the insulation film during the degassing;
determining an endpoint of the degassing based on the amount of released gas, and stopping the degassing at the endpoint; and
depositing a metal film on the insulation film after the degassing.

2. The method of claim 1, wherein:
degassing comprises heating the insulation film by radiating infrared rays on the insulation film.

3. The method of claim 1, wherein:
degassing comprises heating the insulation film with a hot plate.

4. The method of claim 1, wherein the amount of released gas is monitored by thermal desorption spectroscopy.

5. The method of claim 1, wherein:
monitoring the amount of released gas comprises monitoring the amount in a unit time periodically and repeatedly.

6. The method of claim 1, wherein:
monitoring the amount of released gas comprises monitoring the amount of each of a plurality of gasses, when the plurality of gasses are released from the insulation film.

7. The method of claim 1, wherein:
monitoring the amount of released gas comprises monitoring the amount of at least one gas from among a plurality of gasses, when the plurality of gasses are released from the insulation film.

8. The method of claim 5, wherein:
determining the endpoint is based on a total value of the amount of released gas in the unit time.

9. The method of claim 5, wherein:
determining the endpoint is based on the amount of released gas monitored in a prior period of time.

10. The method of claim 1, further comprising:
delineating a pattern on the insulation film before starting the degassing.

11. The method of claim 1, wherein the insulation film contains a material selected from a group consisting of silicon carbonate hydride, silicon carbonate oxidize, silicon carbonate nitride, silicon carbonate, silicon hydrogen, and silicon oxidize.

12. The method of claim 1, wherein the metal film contains a material selected from a group consisting of tantalum, tantalum nitride, titanium, titanium nitride, tungsten nitride, niobium and niobium nitride.

13. The method of claim 1, wherein gas emitted from the insulation film in the degassing contains at least one of water vapor, hydrogen molecules, carbon monoxide, carbon dioxide and oxygen molecules.

14. An apparatus for manufacturing a semiconductor device, comprising:
a process chamber configured to contain a substrate having an insulation film;
a heating unit configured to degas the substrate;
a gas monitor configured to monitor an amount of gas released from the insulation film;
a controller configured to control the heating unit to stop the degassing, by determining an endpoint of the degassing using the monitored amount of the released gas; and
a film deposition unit configured to deposit a metal film on the insulation film.

15. The apparatus of claim 14, wherein the heating unit and the film deposition unit are inside the process chamber.

16. The apparatus of claim 14, further comprising:
a second process chamber, which is different from the process chamber, connected to the process chamber; and
a transfer tool configured to transfer the substrate from the process chamber to the second process chamber.

17. The apparatus of claim 16, wherein the heating unit is inside the process chamber, and the film deposition unit is inside the second process chamber.

18. The apparatus of claim 14, wherein the gas monitor monitors the amount of gas released in a unit time, periodically and repeatedly.

19. The apparatus of claim 14, wherein the gas monitor monitors the amount of each of a plurality of gasses, when the plurality of gasses are released from the insulation film.

20. The apparatus of claim 14, wherein the gas monitor monitors the amount of at least one gas from among a plurality of gasses, when the plurality of gasses are released from the insulation film.
